(19) United States
(12) Patent Application Publication
(10) Pub. No.: US 2023/0395739 A1
(43) Pub. Date: Dec. 7, 2023

(54) ACHROMATIC LUMINESCENT SOLAR CONCENTRATORS

(71) Applicant: ENI S.P.A., Roma (IT)

(72) Inventors: Liliana GILA, Novara (IT); Luciano CACCIANOTTI, Novara (IT); Antonio Alfonso PROTO, Novara (IT)

(21) Appl. No.: 18/249,103

(22) PCT Filed: Oct. 13, 2021
(86) PCT No.: PCT/IB2021/059390

§ 371 Date: Apr. 14, 2023

(30) Foreign Application Priority Data
Oct. 16, 2020 (IT) 102020000024481

(51) Int. Cl. H01L 31/055; H01L 31/048

(52) U.S. Cl. CPC H01L 31/055; H01L 31/048

(57) ABSTRACT

Achromatic luminescent solar concentrator (LSC) includes
a first sheet comprising a matrix of transparent material and at least one first photoluminescent organic compound having an absorption range from 400-550 nm, and an emission range from 500-650 nm, and at least one second photoluminescent organic compound having an absorption range from 420-650 nm, and an emission range from 580-750 nm,
A second sheet is included having a matrix of transparent material and at least one third organic compound, optionally photoluminescent, having an absorption range from 550-750 nm, and an emission range from 700-900 nm.

The LSC can be advantageously used in various applications that require the production of electricity through the exploitation of light energy, in particular solar radiation energy such as, for example: building integrated photovoltaic systems; photovoltaic windows; greenhouses; photo-bioreactors; noise barriers; lighting; design; advertising; automotive industry. LSC is suitable for application in double glazing.

### CROSS-REFERENCE TO RELATED APPLICATIONS

This application is a 35 U.S.C. § 371 National Stage patent application of PCT/IB2021/059390 filed 13 Oct. 2021, which claims the benefit of Italian patent application 102020000024481 filed 16 Oct. 2020, the disclosures of which are incorporated herein by reference in their entirety.

### TECHNICAL FIELD

The present disclosure relates to achromatic luminescent solar concentrators (LSCs).

More particularly, the present disclosure relates to an achromatic luminescent solar concentrator (LSC) comprising a first sheet comprising a matrix of transparent material, at least one first photoluminescent organic compound and at least one second photoluminescent organic compound; a second sheet comprising a matrix of transparent material and at least one third organic compound, optionally photoluminescent; said first, second and third organic compound having specific absorption and emission ranges.

Said achromatic luminescent solar concentrator (LSC) can be advantageously used in various applications that require the production of electricity through the exploitation of light energy, in particular solar radiation energy such as, for example: building integrated photovoltaic (BIPV) systems; photovoltaic windows; greenhouses; photo-bioreactors; noise barriers; lighting; design; advertising; automotive industry. In addition, said achromatic luminescent solar concentrator (LSC) is particularly suitable for application in double glazing.

### BACKGROUND

In the state of the art, one of the main limits to the exploitation of solar radiation energy is represented by the capability of photovoltaic devices (or solar devices) to optimally absorb only the radiations having wavelengths that fall within a narrow spectral range.

With a spectral range from solar radiations extending from wavelengths of about 300 nm to wavelengths of about 2500 nm, photovoltaic cells (or solar cells) based on crystalline silicon have, for example, an optimal energy conversion zone in the range 900 nm-1100 nm, while polymeric photovoltaic cells (or solar cells) are liable to damage if exposed to radiations with wavelengths lower than about 500 nm, due to phenomena of induced photodegradation which become significant below this limit. Typically, the efficiency of the photovoltaic devices (or solar devices) of the state of the art is maximum in the region of the spectrum between 570 nm and 680 nm (yellow-orange).

The aforementioned drawbacks involve a limited external quantum efficiency (EQE) of the photovoltaic devices (or solar devices), defined as the ratio between the number of electron-hole pairs generated in the semiconductor material of photovoltaic devices (or solar devices) and the number of photons that are incident on said photovoltaic devices (or solar devices).

In order to improve the external quantum efficiency (EQE) of the photovoltaic devices (or solar devices), instruments have been developed that, interposed between the source of light radiations (the sun) and the photovoltaic devices (or solar devices), selectively absorb incident radiations having wavelengths outside the effective spectrum of said photovoltaic devices (or solar devices), emitting the absorbed energy in the form of photons with a wavelength included in the effective spectrum. Said instruments are called “luminescent solar concentrators” (LSCs). When the energy of the photons re-emitted by the luminescent solar concentrators (LSCs) is higher than that of the incident photons, the photoluminescence process, comprising the absorption of solar radiations and the subsequent re-emission of photons at a shorter wavelength, is also called an up-conversion process. Conversely, when the energy of the photons that are emitted by luminescent solar concentrators (LSCs) is lower than that of the incident photons, the photoluminescence process is called down-conversion process (or down-shifting).

Generally, said luminescent solar concentrators (LSCs) consist of large sheets made of a material that is transparent to solar radiations (for example, polymeric materials or glasses), inside which photoluminescent compounds acting as spectrum converters are either dispersed, or chemically linked to said polymeric materials, or are deposited on the surface of said polymeric materials or glasses. Due to the optical phenomenon of total reflection, the radiations emitted by the photoluminescent compounds are “guided” towards the thin edges of the sheet where they are concentrated on photovoltaic cells (or solar cells) placed therein. In this way, large surfaces of low-cost materials (photoluminescent sheets) can be used to concentrate light on small surfaces of high-cost materials [photovoltaic cells (or solar cells)].

The photoluminescent compounds can be deposited on the glass or polymeric material support in the form of a thin film or, in the case of polymeric materials, they can be dispersed inside the polymeric matrix. Alternatively, the polymeric matrix can be directly functionalized with photoluminescent chromophoric groups.

As is known, the aforesaid photoluminescent compounds can be of an organic nature (for example, compounds comprising aromatic rings), or of an inorganic nature (for example, quantum dots).

Photoluminescent compounds of an organic nature generally have absorption ranges and emission ranges in the visible zone (400 nm-800 nm), which is the most energetic zone of the solar spectrum. In order to make the most of this energy, with a consequent improvement in the performance of the luminescent solar concentrators (LSCs), systems were used comprising various photoluminescent compounds capable of absorbing and emitting in different zones of the visible spectrum, thus covering a larger zone than that covered by a single photoluminescent compound, that is the so-called “multi-dye systems” which generally comprise photoluminescent compounds that absorb and emit at certain wavelengths, preferably at wavelengths between 400 nm and 700 nm, so that the energy emitted by a photoluminescent compound is reabsorbed by another photoluminescent compound and further re-emitted, and so on, in order to exploit a wider spectral range from the solar radiation.

For example, in the late 1970s, Schwartz B. A. et al., in “Optics Letters” (1977), Vol. 1, No. 2, pp. 73-75, describe a planar solar concentrator consisting of a polymethyl methacrylate (PMMA) sheet comprising a mixture of two photoluminescent compounds, i.e. Coumarin 6 and Rhodamine 6G (at a concentration equal to about 10⁻⁴ M). The current produced by a silicon photovoltaic cell positioned on one side of said sheet was measured and compared with that of a reference planar solar concentrator consisting of a polymethyl methacrylate (PMMA) sheet containing only Coumarin 6 (at a concentration equal to about 10⁻⁴ M). The planar solar concentrator consisting of a polymethyl methacrylate (PMMA) sheet comprising the mixture of the two photoluminescent compounds, was found to allow a current production equal to about twice that produced by the polymethyl methacrylate (PMMA) sheet comprising only Coumarin 6, demonstrating that Coumarin 6 (electron donor compound) was able to absorb part of the solar energy and transfer it to Rhodamine 6G (electron acceptor compound) which was able to re-emit it at a greater wavelength covering a range of the solar spectrum higher than that covered by Coumarin 6 alone or by Rhodamine 6G alone.

Bailey S. T. et al., in “Solar Energy Materials & Solar Cells” (2007), Vol. 91, pp. 67-75, describe a luminescent solar concentrator (LSC) consisting of a thin film of methyl acrylate/ethyl methacrylate copolymer comprising one, two or three photoluminescent compound(s). As the thickness of the films is generally less than that of the sheets (i.e. μm vs mm) the aim was to maximise the proximity among the molecules in order to have a non-radiative energy transfer (FRET—“Forster Resonance Energy Transfer”) so as to improve performance. The photoluminescent compounds used were derivatives of 4,4-difluoro-4-boron-3a,4a-diaza-s-indacene (BODIPY) respectively BODIPY 494/505, BODIPY 535/558 and BODIPY 564/591 (where the numbers correspond to the absorption and emission wavelengths, respectively). Each film was prepared by casting by depositing a solution of the dye(s) onto the thin film of the aforesaid copolymer at a concentration equal to 1×10⁻² M. The luminescent solar concentrator (LSC) comprising three different photoluminescent compounds was found to absorb 70% of the photons in the range 350 nm-650 nm, about 1.5 times more than the luminescent solar concentrator (LSC) comprising the best of the single dyes, and the device, prepared by positioning two PV cells on one edge of the sheet, showed a 30% increase in efficiency.

Goldschmidt J. C. et al. in “Solar Energy Materials & Solar Cells” (2009), Vol. 93, pp. 176-182, again with the aim of improving the efficiency of the luminescent solar concentrators (LSCs), describe a device obtained by combining two luminescent solar concentrators (LSCs) each comprising a different photoluminescent compound. The final device was formed by two stacked luminescent solar concentrators (LSCs), each 2×2×0.3 cm in size, with four GaInP solar cells, one on each side: each single solar cell was 6 mm high, so that each solar cell received light from both concentrators. The device with the two luminescent solar concentrators (LSCs) showed an efficiency equal to 6.7%, while the device with only one luminescent solar concentrator (LSC) comprising the most efficient of the photoluminescent compounds used showed an efficiency equal to 5.1%.

Liu C. et al., in “Journal of Optics” (2015), Vol. 17, 025901, describe a device obtained by combining three luminescent solar concentrator (LSCs) each comprising a different photoluminescent compound, in particular, a red photoluminescent compound (Lumogen® F Red 305), a green photoluminescent compound (Coumarin 6) and a perylene blue photoluminescent compound, respectively. Strings of monocrystalline silicon solar cells measuring 5×0.5 cm were glued to the edges of each sheet: the device obtained, consisting of the three superimposed sheets and of the solar cells, showed a power conversion efficiency equal to 1.4%, said efficiency being 16.7% higher than that obtained from a device comprising the luminescent solar concentrator (LSC) with only the red photoluminescent compound (Lumogen® F Red 305).

Earp A. A. et al. in “Solar Energy Materials & Solar Cells” (2004), Vol. 84, pp. 411-426, describe a device comprising a luminescent solar concentrator (LSC) consisting of three polymethyl methacrylate (PMMA) sheets comprising three different photoluminescent compounds, violet, green and pink, capable of generating white light. Said luminescent solar concentrator (LSC) was placed on the roof of a building or near the windows of the rooms and the waveguides emitted by each dye are collected and connected into a single transparent polymethyl methacrylate (PMMA) waveguide of over 5 metres long that can reach and illuminate the darkest zones of the building.

The luminescent solar concentrators (LSCs) reported above, which use different dyes, although capable of having improved performance, however they are not achromatic.

According to EU Directives 2010/31/EU and 2012/27/EU, all new buildings must be near zero energy buildings (nZEB), i.e. they must not only be designed to consume as little energy as possible, but must also produce the energy they consume.

Thanks to their high versatility due to transparency, flexibility, a myriad of possible shapes and colours, the luminescent solar concentrators (LSCs) are seen as potential structural energy components for use in building integrated photovoltaic (BIPV) systems, with a significantly improved aesthetic and design value compared to traditional silicon photovoltaic panels.

The colour and the degree of transparency can be modulated by varying the type and the concentration of the photoluminescent compound(s) used and depend on the end use of the luminescent solar concentrator (LSC).

In particular, thanks to their transparency, the luminescent solar concentrators (LSCs) are potential candidates in the construction of photovoltaic windows. For this use, however, achromatic luminescent solar concentrators (LSCs) might be preferred. In fact, the presence of an intensely coloured window in a room might influence the degree and the quality of brightness of the room during the day and, therefore, make it uncomfortable to stay in the same room: therefore, the presence of a photovoltaic window comprising an achromatic luminescent solar concentrator (LSC) would be desirable.

Consequently, studies have been carried out with the aim of obtaining achromatic luminescent solar concentrators (LSCs).

For example, US patent application 2014/0130864 describes a transparent luminescent solar concentrator (LSC) comprising: a transparent waveguide [(for example, polymethyl methacrylate (PMMA)]; and a transparent film including a plurality of transparent luminophores (for example, clusters of metal halide nanocrystals or thiocarbocyanine salts or naphthalocyanine derivatives), said luminophores being capable of absorbing light in the ultraviolet spectrum and of emitting light in the near-infrared spectrum. The aforesaid transparent luminescent solar concentrator (LSC) is said to be advantageously usable in photovoltaic windows.

US patent application 2014/0283896 describes a transparent luminescent solar concentrator (LSC) comprising luminophores incorporated in a waveguide matrix [for example, (poly)-butyl methacrylate-co-methyl methacrylate (PBMMA)] which are capable of both absorbing and selectively emitting light in the near infrared spectrum, (for example, cyanines or salts thereof) so as to enable the operation of photovoltaic cells applied to at least one side or incorporated in said waveguide matrix. The aforesaid luminescent solar concentrator (LSC) is said to be highly transparent to the human eye and, therefore, advantageously usable in photovoltaic windows, greenhouses, car windows, aircraft windows, and the like.

International patent application WO 2016/116803 describes a luminescent solar concentrator (LSC) comprising a polymeric [for example, polymethyl methacrylate (PMMA)] or glassy matrix comprising colloidal nanocrystals, said colloidal nanocrystals being nanocrystals of at least one ternary chalcogenide based on group IB and IIIB metals (group 11 and 16, respectively, in IUPAC nomenclature) and of at least one chalcogen of group IV (group 16 in IUPAC nomenclature). The aforesaid luminescent solar concentrator (LSC) is said to be colourless, i.e. it is said to have a neutral colour (shades of grey similar to normal optical filters having neutral optical density).

Meinardi F. et al, in “Nature Photonics” (2017), Vol. 11, pp. 177-186, describe a luminescent solar concentrator (LSC) comprising silicon quantum dots which, depending on their size, are capable of absorbing in a broad spectrum of solar radiations and of emitting in the infrared spectrum, and of greatly reducing efficiency losses due to reabsorption. Said luminescent solar concentrator (LSC) is said to have an optical efficiency equal to 2.85% and a high degree of transparency across the visible spectrum (70% transmittance) and, therefore, can be advantageously used in building integrated photovoltaic (BIPV) systems, in particular, in photovoltaic windows.

International patent application WO 2019/2020529 in the name of the Applicant, describes a luminescent solar concentrator (LSC) of neutral colour comprising:
at least one first sheet comprising a matrix of transparent material and at least one first photoluminescent organic compound having an absorption range from 400 nm to 550 nm, preferably from 420 nm to 500 nm, and an emission range from 500 nm to 650 nm, preferably from 520 nm to 620 nm;
at least one second sheet comprising a matrix of transparent material and at least one second photoluminescent organic compound having an absorption range from 420 nm to 650 nm, preferably from 480 nm to 600 nm, and an emission range from 580 nm to 750 nm, preferably from 600 nm to 700 nm;
at least one third sheet comprising a matrix of transparent material and at least one third organic compound, optionally photoluminescent, having an absorption range from 550 nm to 750 nm, preferably from 570 nm to 700 nm, and an emission range from 700 nm to 900 nm, preferably from 740 nm to 850 nm.

Since the use of achromatic luminescent solar concentrators (LSCs) in various applications requiring the production of electricity by exploiting light energy, in particular solar radiation energy, such as, for example: building integrated photovoltaic (BIPV) systems, photovoltaic windows, greenhouses, photo-bioreactors, noise barriers, lighting, design, advertising, automotive industry, is of great interest, the production of new achromatic luminescent solar concentrators (LSCs) is of great interest, as well.

The Applicant has set itself the problem of finding achromatic luminescent solar concentrators (LSCs) that are able to give comparable or even greater performance, in particular in terms of the power generated by the photovoltaic devices (or solar devices) in which they are used, than the known ones.

The Applicant has now found achromatic luminescent solar concentrator (LSCs) comprising a first sheet comprising a matrix of transparent material, at least one first photoluminescent organic compound and at least one second photoluminescent organic compound; a second sheet comprising a matrix of transparent material and at least one third organic compound, optionally photoluminescent; said first, second and third organic compound having specific absorption and emission ranges. In particular, the Applicant has found that by superimposing said two sheets, it is possible to obtain achromatic luminescent solar concentrators (LSCs) capable of maintaining the performance, in particular in terms of efficiency, of the photovoltaic devices (or solar devices) in which they are used, compared to known ones.

In addition, the use of only two sheets provides numerous advantages such as, for example:
the transmission of light in a more natural way as the light has to pass through fewer surfaces, thus avoiding losses of brightness inside the room;
the assembly of the components becomes easier and faster due to the smaller number of components to be assembled.

Furthermore, said achromatic luminescent solar concentrators (LSCs) can be advantageously used in various applications that require the production of electricity through the exploitation of light energy, in particular solar radiation energy such as, for example: building integrated photovoltaic (BIPV) systems; photovoltaic windows; greenhouses; photo-bioreactors; noise barriers; lighting; design; advertising; automotive industry. In addition, the achromatic luminescent solar concentrators (LSCs) object of the present disclosure are particularly suitable for application in double glazing.

Therefore, the present disclosure provides an achromatic luminescent solar concentrator (LSC) comprising:
a first sheet comprising a matrix of transparent material and at least one first photoluminescent organic compound having an absorption range from 400 nm to 550 nm, preferably from 420 nm to 500 nm, and an emission range from 500 nm to 650 nm, preferably from 520 nm to 620 nm, and at least one second photoluminescent organic compound having an absorption range from 420 nm to 650 nm, preferably from 480 nm to 600 nm, and an emission range from 580 nm to 750 nm, preferably from 600 nm to 700 nm;
a second sheet comprising a matrix of transparent material and at least one third organic compound, optionally photoluminescent, having an absorption range from 550 nm to 750 nm, preferably from 570 nm to 700 nm, and an emission range from 700 nm to 900 nm, preferably from 740 nm to 850 nm.

For the purpose of the present description and the following claims, the definitions of the numerical ranges always comprise the extreme values unless otherwise specified.

For the purpose of the present description and the following claims, the term “comprising” also includes the terms “which essentially consists of” or “which consists of”.

Alternatively, said second sheet may comprise a matrix of transparent material and at least one non-fluorescent transparent adhesive film.

Consequently, the present disclosure further provides an achromatic luminescent solar concentrator (LSC) comprising:
a first sheet comprising a matrix of transparent material and at least one first photoluminescent organic compound having an absorption range from 400 nm to 550 nm, preferably from 420 nm to 500 nm, and an emission range from 500 nm to 650 nm, preferably from 520 nm to 620 nm, and at least one second photoluminescent organic compound having an absorption range from 420 nm to 650 nm, preferably from 480 nm to 600 nm, and an emission range from 580 nm to 750 nm, preferably from 600 nm to 700 nm;
a second sheet comprising a matrix of transparent material and at least one non-fluorescent transparent adhesive film, said non-fluorescent transparent adhesive film being preferably placed on the major upper surface of said second sheet.

In accordance with a preferred embodiment of the present disclosure, said first sheet and said second sheet have an upper surface, a lower surface and one or more external sides. According to an embodiment, said first sheet and said second sheet, may have one external side (e.g., they may be circular), three, four, five, six, seven, or more sides. According to an embodiment, said first sheet and said second sheet may have a lower surface spaced apart from the upper surface in which the external side(s) extend(s) from the upper to the lower surface.

In accordance with a preferred embodiment of the present disclosure, said first sheet and said second sheet are superimposed on each other so that the major surfaces of said first sheet and of said second sheets are in direct contact with each other.

In accordance with a further preferred embodiment of the present disclosure, the major lower surface of said first sheet is in direct contact with the major upper surface of said second sheet.

For the purpose of the present description and the following claims, the term “in direct contact” means that there is no interposition of further elements between said first sheet and said second sheet.

In order to improve the performance of photovoltaic devices (or solar devices) in which achromatic luminescent solar concentrators (LSCs) object of the present disclosure are used, in particular in terms of power generated by said photovoltaic devices (or solar devices), the order of superposition of said first sheet and said second sheet is important.

In accordance with a further embodiment of the present disclosure, the major upper surface of said first sheet is closer to the photon source and the major lower surface of said second sheet is more away from the photon source.

In accordance with a preferred embodiment of the present disclosure, said transparent material may be selected, for example, from: transparent polymers such as, for example, polymethyl methacrylate (PMMA), polycarbonate (PC), polyisobutyl methacrylate, poly ethyl methacrylate, polyallyl diglycol carbonate, polymethacrylamide, polycarbonate ether, polyethylene terephthalate, polyvinylbutyral, ethylene-vinyl acetate copolymers, ethylene-tetrafluoroethylene copolymers, polyimide, polyurethane, styrene-acrylonitrile copolymers, styrene-butadiene copolymers, polystyrene, methyl methacrylate styrene copolymers, polyether sulfone, polysulfone, cellulose triacetate, transparent and impact resistant cross-linked acrylic compositions consisting of a brittle matrix (I) having a glass transition temperature (T_{g}) higher than 0° C. and elastomeric domains having dimensions lower than 100 nm consisting of macromolecular sequences (II) having a flexible nature with a glass transition temperature (T_{g}) lower than 0° C. described, for example, in US patent application US 2015/0038650 (hereinafter referred to, for simplicity, as PMMA-IR), or mixtures thereof; transparent glasses such as, for example, silica, quartz, alumina, titania, or mixtures thereof. Polymethyl methacrylate (PMMA), PMMA-IR, or mixtures thereof, are preferred. Preferably said transparent material may have a refractive index ranging from 1.30 to 1.70.

In accordance with a preferred embodiment of the present disclosure, said at least one first photoluminescent organic compound may be selected, for example, from:
benzothiazole compounds such as, for example, 4,7-di(thien-2′-yl)-2,1,3-benzothiazole (DTB), or mixtures thereof;
disubstituted benzoheterodiazole compounds such as, for example, 4,7-bis[5-(2,6-dimethylphenyl)-2-thienyl]benzo[c]1,2,5-thiadiazole (MPDTB), 4,7-bis[5-(2,6-di-iso-propylphenyl)-2-thienyl]benzo[c]1,2,5-thiadiazole (IPPDTB), 4,7-bis[4,5-(2,6-dimethylphenyl)-2-thienyl]benzo[c]1,2,5-thiadiazole (2MPDTB), or mixtures thereof;
disubstituted diaryloxybenzoheterodiazole compounds such as, for example, 5,6-diphenoxy-4,7-bis(2-thienyl)-2,1,3-benzothiadiazole (DTBOP), 5,6-diphenoxy-4,7-bis[5-(2,6-dimethylphenyl)-2-thienyl]-benzo-[c]1,2,5-thiadiazole (MPDTBOP), 5,6-diphenoxy -4,7-bis[5-(2,5-dimethylphenyl)-2-thienyl]benzo[c]1,2,5-thiadiazole (PPDTBOP), 5,6-diphenoxy-4,7-bis[5-(2,5-dimethylphenyl)-2-thienyl]benzo[c]-1,2,5-thiadiazole (PPDTBOP), 5,6-diphenoxy-4,7-bis[5-(2,6-diisopropyl-phenyl)-2-thienyl]benzo[c]1,2,5-thiadiazole (IPPDTBOP), or mixtures thereof;
perylene and perylene imide compounds such as, for example, compounds known under the trade name of Lumogen® F083, Lumogen® F170, Lumogen® F240, from Basf, or mixtures thereof;
benzopyranone compounds such as, for example, the compounds known under the trade name of Coumarin 6, Coumarin 30, from Acros, or mixtures thereof; or mixtures thereof.

In accordance with a further preferred embodiment of the present disclosure, said at least one first photoluminescent organic compound is 5,6-diphenoxy-4,7-bis[5-(2,6-dimethylphenyl)-2-thienyl]benzo[c]1,2,5-thiadiazole (MPDTBOP).

More details relating to said disubstituted benzoheterodiazole compounds and disubstituted diaryloxybenzoheterodiazole compounds can be found, for example, in international patent applications WO 2016/046310 and WO 2016/046319 in the name of the Applicant.

In accordance with a preferred embodiment of the present disclosure, said at least one second photoluminescent organic compound may be selected, for example from:
disubstituted benzoheterodiazole compounds such as, for example, 4,7-bis[5-(2,5-dimethoxypheny)-2-thienyl]benzo[c]1,2,5-thiadiazole, 4,7-bis[5-(2,6-dimethoxyphenyl)-2-thienyl]benzo[c]1,2,5-thiadiazole, 4,7-bis[5-(2,4-dimethoxyphenyl)-2-thienyl]benzo[c]1,2,5-thiadiazole, or mixtures thereof;
disubstituted diaryloxybenzoheterodiazole compounds such as, for example, 5,6-diphenoxy-4,7-bis[5-(2-naphthyl)-2-thienyl]benzo[c]1,2,5-thiadiazole, or mixtures thereof;
compounds comprising a benzoheterodiazole group and at least one benzodithiophene group such as, for example, 4,7-bis(7′,8′-dibutyl-benzo[1′,2′-b′:4′,3′-b″]ditien-5′-yl)-benzo[c][1,2,5]thiadiazole (F500), or mixtures thereof;
disubstituted naphthothiadiazole compounds such as, for example, 4,9-bis (7′,8′-dibutyl-benzo[1′,2′-b′:4′,3′-b″]ditien-5′-yl)-naphtho[2,3-c][1,2,5]-thiadiazole (F521), 4,9-bis(thien-2′-yl)-naphtho[2,3-c][1,2,5]thiadiazole (DTN), or mixtures thereof;
benzothiadiazole dithiophenic compounds such as, for example, 4,7-bis(5-(thiophen-2-yl)thiophen-2-yl)benzo[c][1,2,5]thiadiazole (QTB), 4,7-di (5″-n-hexyl-2′, 2″-ditien-5′-yl)-2,1,3-benzothiadiazole (QTB-ex), or mixtures thereof;
perylene compounds such as, for example, N,N′-bis(2′,6′-di-iso-propyl phenyl)(1,6,7,12-tetraphenoxy)(3,4,9,10-perylene-diimide (Lumogen® F Red 305 from Basf), or mixtures thereof;
compounds derived from the family of fluorones such as, for example, compounds known under the trade name of Rhodamine 6G, Rhodamine 101, from Sigma-Aldrich, or mixtures thereof;
   or mixtures thereof.

In accordance with a further preferred embodiment of the present disclosure, said at least one second photoluminescent organic compound is N,N′-bis(2′,6′-di-iso-propylphenyl) (1,6,7,12-tetraphenoxy) (3,4,9,10-perylene-diimide (Lumogen® F Red 305—Basf).

More details relating to said compounds comprising a benzoheterodiazole group and at least one benzodithiophene group can be found, for example, in international patent application WO 2013/098726 in the name of the Applicant.

More details relating to said disubstituted naphthiadiazole compounds can be found, for example, in international patent application WO 2014/128648, in the name of the Applicant.

More details relating to said benzothiadiazole dithiophenic compounds can be found, for example, in European patent application EP 2 557 606, in the name of the Applicant.

More details relating to said disubstituted benzoheterodiazole compounds and disubstituted diaryloxybenzoheterodiazole compounds can be found, for example, in international patent applications WO 2016/046310 and WO 2016/046319 in the name of the Applicant, above reported.

In accordance with a preferred embodiment of the present disclosure, said at least one third organic compound, optionally photoluminescent, may be selected, for example, from:
phenothiazine compounds substituted with alkyl and/or alkyl-amino groups such as, for example, the compound known under the trade name Toluidine blue from Sigma-Aldrich, or mixtures thereof;
phenoxazine compounds such as, for example, the compound known under the trade name Blue Nile A from Sigma-Aldrich, or mixtures thereof;
anthraquinone compounds substituted with alkyl-amino groups such as, for example, the compound known under the trade name Oil Blue N from Sigma-Aldrich, or mixtures thereof;
   or mixtures thereof.

In accordance with a further preferred embodiment of the present disclosure, said at least one third organic compound is Oil Blue N from Sigma Aldrich.

In accordance with a preferred embodiment of the present disclosure, in said first sheet, said at least one first photoluminescent organic compound may be present in said matrix of transparent material in an amount ranging from 8 ppm to 200 ppm, preferably ranging from 10 ppm to 100 ppm, even more preferably ranging from 15 to 40 ppm.

In accordance with a preferred embodiment of the present disclosure, in said first sheet, said at least one second photoluminescent organic compound may be present in said matrix of transparent material in an amount ranging from 5 ppm to 130 ppm, preferably ranging from 7 ppm to 50 ppm, even more preferably ranging from 10 to 30 ppm.

In accordance with a preferred embodiment of the present disclosure, in said second sheet, said at least one third organic compound, optionally photoluminescent, may be present in said matrix of transparent material in an amount ranging from 6 ppm to 150 ppm, preferably ranging from 10 ppm to 60 ppm, even more preferably ranging from 20 to 50 ppm.

For the purpose of the present description and the following claims, the term “ppm” means milligrams (mg) of photoluminescent organic compound or of organic compound, optionally photoluminescent, per 1 kilogram (kg) of matrix of transparent material.

It should be noted that for the purpose of the present disclosure, indicatively the amount of photoluminescent organic compound or of organic compound optionally photoluminescent, to be used can be derived by applying the following equation (I) (i.e. Lambert-Beer's law):

Absorbance=ε×[dye]×1 (I)

wherein:
ε is the molar extinction coefficient of the organic compound at a given wavelength (λ);
1 is the optical path.

Having established the desired absorbance value and known the value of the molar extinction coefficient (ε) specific to each photoluminescent organic compound and to each organic compound optionally photoluminescent, the required amount is derived. Said amount must be subsequently corrected due to the partial superposition of the absorption and emission bands of the aforesaid photoluminescent organic compound and organic compound optionally photoluminescent, which modifies the absorbance at certain wavelength values (λ) altering the overall colouring of the sheets.

As reported above, alternatively, said second sheet comprises a matrix of transparent material and a non-fluorescent transparent adhesive film.

In accordance with a preferred embodiment of the present disclosure, said non-fluorescent transparent adhesive film may be selected, for example, from polyethylene terephthalate (PET) films or colored polyvinyl chloride (PVC) films with high optical quality.

For the purpose of the present description and the following claims, the term “high optical quality” means that the non-fluorescent transparent adhesive film is free of additives and physical imperfections which may alter the transmission of light.

Preferably, said non-fluorescent transparent adhesive film is formed by several layers: a transparent acrylic surface layer that gives the film scratch-resistant properties and allows for a good durability of the material, one or more layers of polyethylene terephthalate (PET) or colored polyvinyl chloride (PVC) with high optical quality, an adhesive layer for gluing to the glass or polymer surface, and finally an adhesive protection liner that is peeled off and discarded at the time of application.

A non-fluorescent transparent adhesive film which can be advantageously used for the purpose of the present disclosure and is commercially available is the product Bleu 40C from Solar Screen.

In accordance with a preferred embodiment of the present disclosure, said first sheet and said second sheet may have a thickness ranging from 1 mm to 10 mm, preferably ranging from 2 mm to 8 mm.

The aforesaid photoluminescent organic compounds or optionally photoluminescent, can be used in said achromatic luminescent solar concentrators (LSCs) in various forms.

For example, if the matrix of transparent material is of a polymeric type, said at least one photoluminescent organic compound or said at least one organic compound optionally photoluminescent, may be dispersed in the polymer of said matrix of transparent material by, for example, melt dispersion, or bulk addition, and subsequent formation of a sheet comprising said polymer and said at least one photoluminescent organic compound or said at least one organic compound optionally photoluminescent, by operating, for example, according to the technique called “casting”.

Alternatively, said at least one photoluminescent organic compound or said at least one organic compound optionally photoluminescent, and the polymer of said matrix of transparent material may be solubilized in at least one suitable solvent obtaining a solution which is deposited on a sheet of said polymer, forming a film comprising said at least one photoluminescent organic compound, or said at least one organic compound optionally photoluminescent, and said polymer, by operating, for example, by means of a Doctor Blade-type filmograph: thereafter said solvent is allowed to evaporate. Said solvent may be selected, for example, from: hydrocarbons, for example, 1,2-dichlorobenzene; esters, for example, phenyl acetate, ethyl acetate, methyl benzoate, methyl acetoacetate; or mixtures thereof.

In case the matrix of transparent material is of glassy type, said at least one photoluminescent organic compound or said at least one organic compound optionally photoluminescent, can be solubilized in at least one suitable solvent (which can be selected from those reported above) obtaining a solution which is deposited on a sheet of said transparent matrix of glassy type, forming a film comprising said at least one photoluminescent organic compound or said at least one organic compound optionally photoluminescent, by operating, for example, by means of a Doctor Blade-type filmograph: thereafter said solvent is allowed to evaporate.

Alternatively, a sheet of said matrix of transparent material of polymeric type may be immersed in an aqueous microemulsion comprising said at least one photoluminescent organic compound or said at least one organic compound optionally photoluminescent, prepared in advance. More details relating to said microemulsions can be found, for example, in US patent application U.S. Pat. No. 9,853,172 in the name of the Applicant.

For the purpose of the present disclosure, said sheets can be made by operating according to the technique called “casting”: more details can be found in the following examples. Subsequently, the sheets thus obtained are superimposed.

As mentioned above, the achromatic luminescent solar concentrator (LSC) object of the present disclosure is particularly suitable for an application in double glazing.

Double glazing, i.e. an insulating glass formed by two or more coupled glasses separated by an interspace of dehydrated air or gas, is now commonly used in the field of the windows and doors of a building because of its thermal and/or acoustic insulation properties.

In general, double glazing comprising luminescent solar concentrators (LSCs) can be built by inserting said luminescent solar concentrators (LSCs) on the edges of which photovoltaic cells (or solar cells) have been placed in the interspace between the two glasses. The thickness of the interspace can generally be between 6 mm and 15 mm, which allows a limited number of sheets to be inserted depending on the thickness of the same sheets.

Therefore, a further object of the present disclosure is a double glazing comprising at least one achromatic luminescent solar concentrator (LSC) defined above.

If a non-fluorescent transparent adhesive film is used, it can be glued directly on a glass of the double glazing, thus limiting the number of sheets to be inserted inside the double glazing to the first sheet only.

Therefore, a further object of the present disclosure is a double glazing comprising:
at least one achromatic luminescent solar concentrator (LSC) comprising a sheet comprising a matrix of transparent material and at least one first photoluminescent organic compound having an absorption range from 400 nm to 550 nm, preferably from 420 nm to 500 nm, and an emission range from 500 nm to 650 nm, preferably from 520 nm to 620 nm and at least one second photoluminescent organic compound having an absorption range from 420 nm to 650 nm, preferably from 480 nm to 600 nm, and an emission range from 580 nm to 750 nm, preferably from 600 nm to 700 nm;
at least one non-fluorescent transparent adhesive film glued directly on a glass of the double-glazing, preferably on the innermost glass.

In said double-glazing, said first photoluminescent organic compound, said second photoluminescent organic compound and said non-fluorescent transparent adhesive film, are selected from among those reported above.

A further object of the present disclosure is also a photovoltaic device (or solar device) comprising at least one photovoltaic cell (or solar cell), and at least one achromatic luminescent solar concentrator (LSC) defined above.

Said photovoltaic device (or solar device) can be obtained, for example, by assembling the aforesaid achromatic luminescent solar concentrator (LSC) with at least one photovoltaic cell (or solar cell).

For the purpose of the present disclosure, one or more photovoltaic cells (or solar cells) may be placed outside at least one side of said achromatic luminescent solar concentrator (LSC), preferably said photovoltaic cells (or solar cells) may partially, or completely, cover the external perimeter of said achromatic luminescent solar concentrator (LSC).

For the purpose of the present description and the following claims, the term “external perimeter” means the external sides of said achromatic luminescent solar concentrator (LSC).

### BRIEF DESCRIPTION OF THE DRAWINGS

The present disclosure will now be illustrated in greater detail through some embodiments with reference to FIGS. 1-3 reported below.

In particular, FIG. 1 depicts the assembly of an achromatic (D) luminescent solar concentrator (LSC) in accordance with an embodiment of the present disclosure. For this purpose, a frame of photovoltaic cells (or solar cells) (3) connected in series and with a multimeter (4), was glued around the four external sides of a first sheet (1), said first sheet (1) comprising a matrix of transparent material [e.g, polymethyl methacrylate (PMMA)], a first photoluminescent organic compound [e.g., 5,6-diphenoxy-4,7-bis[5-(2,6-dimethylphenyl)-2-thienyl]benzo[c]1,2,5-thiadiazole (MPDTBOP)] and a second organic compound [e.g., N,N′-bis(2′,6′-di-iso-propylphenyl)(1,6,7,12-tetraphenoxy)(3,4,9,10-perylenediimide (Lumogen® F Red 305 from Basf)]. Subsequently, the major lower surface of said first sheet (1) was placed in direct contact with the major upper surface of a second sheet (2), said second sheet (2) comprising a matrix of transparent material [e.g., polymethyl methacrylate (PMMA)] and a third non-photoluminescent organic compound (e.g., Oil Blue N from Sigma Aldrich). The major upper surface of said first sheet (1) is the one closer to the photon source [i.e. solar radiations (S)] and the major lower surface of said second sheet (2) is the one more away from the photon source [i.e. solar radiations (S)].

FIG. 2 depicts the assembly of an achromatic (D) luminescent solar concentrator (LSC) in accordance with a further embodiment of the present disclosure. For this purpose, a frame of photovoltaic cells (or solar cells) (3) connected in series and with a multimeter (4), was glued around the four external sides of a first sheet (1), said first sheet (1) comprising a matrix of transparent material [e.g, polymethyl methacrylate (PMMA)], a first photoluminescent organic compound [e.g., 5,6-diphenoxy-4,7-bis[5-(2,6-dimethylphenyl)-2-thienyl]benzo[c]1,2,5-thiadiazole (MPDTBOP)] and a second organic compound [e.g., N,N′-bis(2′,6′-di-iso-propylphenyl)(1,6,7,12-tetraphenoxy)(3,4,9,10-perylenediimide (Lumogen® F Red 305 from Basf)]. Subsequently, the major lower surface of said first sheet (1) was placed in direct contact with the major upper surface of a second sheet (2), said second sheet (2) comprising a matrix of transparent material [e.g., polymethyl methacrylate (PMMA)] and a transparent non-photoluminescent adhesive film (e.g., Bleu 40C from Solar Screen), said transparent non-photoluminescent adhesive film being placed on the major upper surface of said second sheet. The major upper surface of said first sheet (1) is the one closer to the photon source [i.e. solar radiations (S)] and the major lower surface of said second sheet (2) is the one more away from the photon source [i.e. solar radiations (S)].

FIG. 3 depicts a double glazing (V) in accordance with a further embodiment of the present disclosure comprising an achromatic luminescent solar concentrator (LSC). For this purpose, the achromatic luminescent solar concentrator (LSC) comprising a sheet (1) around the four external sides of which, as reported above, a frame of photovoltaic cells (or solar cells) (2) connected in series and with a multimeter (3) was glued, said sheet (1) comprising a matrix of transparent material [e.g, polymethyl methacrylate (PMMA)], a first photoluminescent organic compound [e.g., 5,6-diphenoxy-4,7-bis[5-(2,6-dimethylphenyl)-2-thienyl]benzo[c]1,2,5-thiadiazole (MPDTBOP)] and a second organic compound [e.g., N,N′-bis(2′,6′-di-iso-propylphenyl)(1,6,7,12-tetraphenoxy)(3,4,9,10-perylenediimide (Lumogen® F Red 305 from Basf)], was introduced into a double glazing (V). The transparent, non-photoluminescent adhesive film (e.g., Blue 40 C of Solar Screen) was glued directly on the inner glass of the double glazing (4). The major upper surface of said sheet (1) is the one closer to the photon source [i.e. solar radiations (S)] and the glass to which the transparent non-photoluminescent adhesive film (4) has been glued is the one more away from the photon source [i.e. solar radiation (S)].

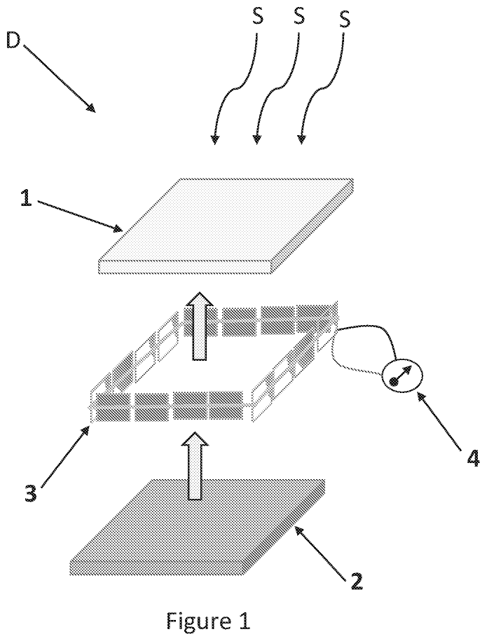

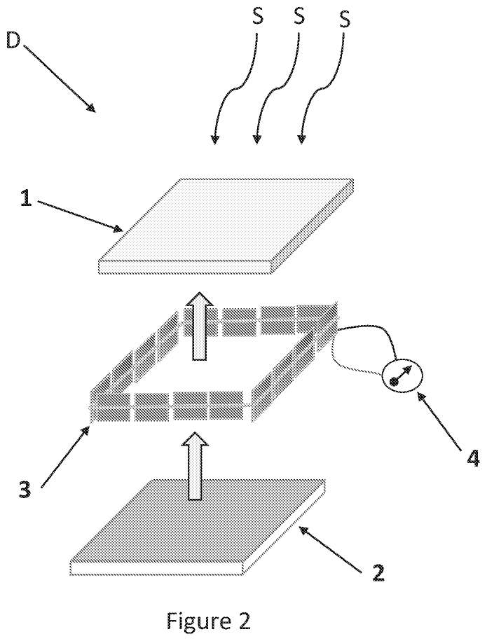

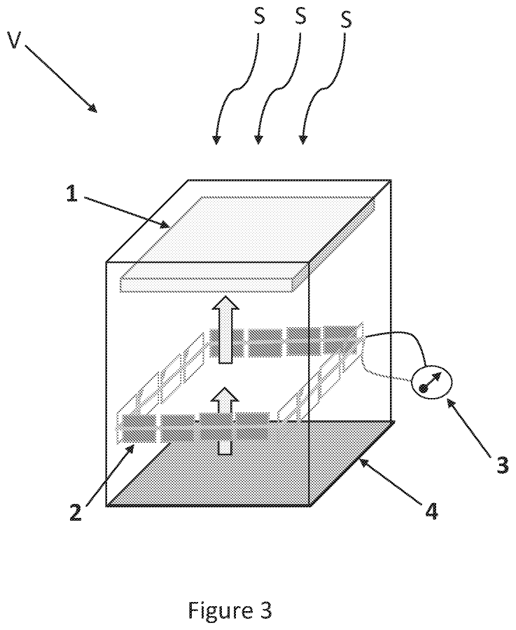

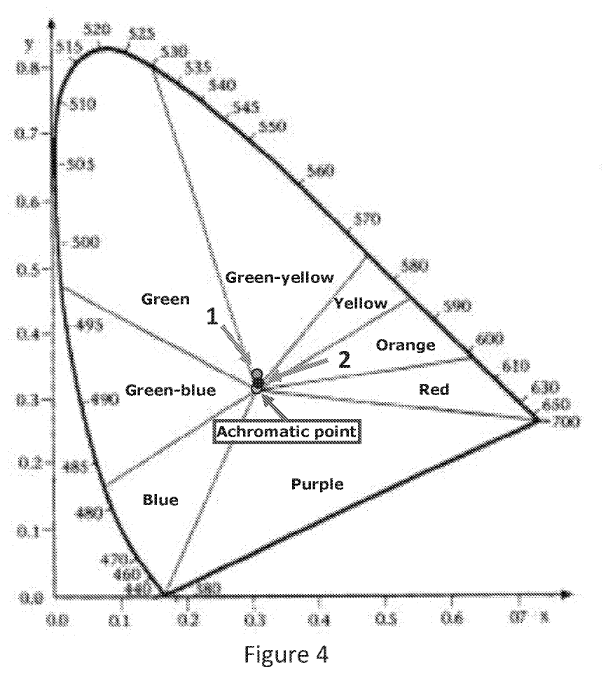

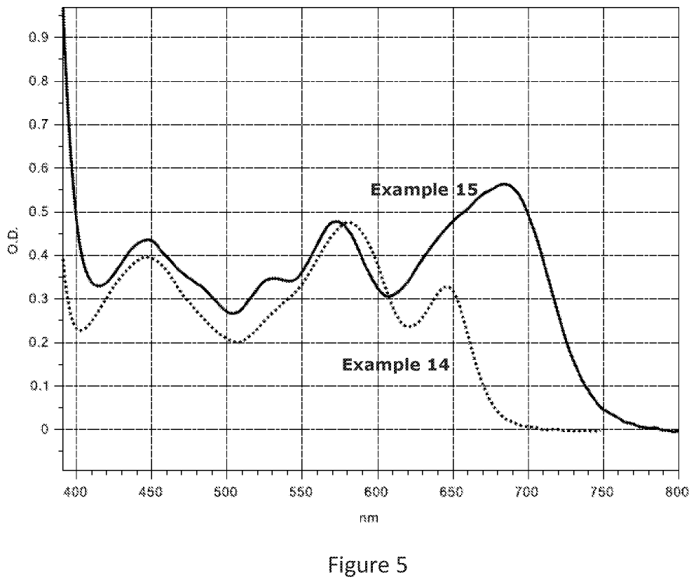

### DETAILED DESCRIPTION OF THE DISCLOSURE

In order to better understand the present disclosure and to put it into practice, some illustrative and non-limiting examples thereof are reported below.

### EXAMPLE 1

### Preparation of Sheet 1a

In a 1-litre flask, 400 ml of methyl methacrylate (MMA) (Sigma-Aldrich), previously distilled in order to remove any polymerisation inhibitors, were heated under magnetic stirring, bringing the temperature to 80° C., in 2 hours. Subsequently, 40 mg of 2,2′-azobis(2-methylpropionitrile) (AIBN) (Sigma-Aldrich) (initiator) dissolved in 40 ml of methyl methacrylate (MMA) (Sigma-Aldrich), previously distilled, were added: the temperature of the mixture obtained decreases by about 3° C.-4° C. Subsequently, said mixture was heated bringing the temperature to 94° C., in 1 hour: the whole was left at said temperature, under stirring, for 2 minutes, and subsequently cooled in an ice bath obtaining a pre-polymerised polymethyl methacrylate (PMMA) syrup.

Subsequently, a mould was prepared assembled with two glass sheets having a thickness equal to 10 mm and larger dimensions equal to 300×300 mm, separated by a polyvinyl chloride (PVC) seal with a diameter equal to 10 mm: the sheets were then mounted between metal jaws and clamped until obtaining a space between the two sheets equal to 3 mm.

Then, in a 1-litre glass flask, 400 ml of pre-polymerised polymethyl methacrylate (PMMA) syrup obtained as described above, 25 mg of lauroyl peroxide (Sigma-Aldrich) dissolved in 40 ml of methyl methacrylate (MMA) (Sigma-Aldrich), previously distilled, an amount of 5,6-diphenoxy-4,7-bis[5-(2,6-dimethylphenyl)-2-thienyl]benzo[c]1,2,5-thiadiazole (MPDTBOP), obtained as described in Example 7 of international patent application WO 2016/046319 in the name of the Applicant above reported, equal to 35 ppm and 5000 ppm of Tinuvin® P (Basf) were loaded: the obtained mixture was kept under magnetic stirring and under vacuum (10 mm Hg), for 45 minutes, at room temperature (25° C.), obtaining a degassed solution. The solution thus obtained was poured into the mould prepared as described above until it was full: subsequently, after closing the opening used for filling with a seal, the mould was immersed into a water bath at 55° C., for 48 hours. The mould was then placed in an oven at 95° C., for 24 hours (curing step), then removed from the oven and allowed to cool to room temperature (25° C.). Subsequently, the metal jaws and the seal were removed, and the glass sheets were separated, obtaining the sheet 1a (dimensions 250×250×3 mm).

### EXAMPLE 2

### Preparation of Sheet 1b

The sheet 1b was prepared by operating as reported in Example 1, except that instead of 5,6-diphenoxy-4,7-bis[5-(2,6-dimethylphenyenyl)-2-thienyl]benzo[c]1,2,5-thiadiazole (MPDTBOP), use was made of N,N′-bis(2′,6′-di-iso-propylphenyl)(1,6,7,12-tetraphenoxy)(3,4,9,10-perylene-diimide (Lumogen® F Red 305—Basf) in an amount equal to 21.6 ppm, obtaining the sheet 1b (size 250×250×3 mm).

### EXAMPLE 3

### Preparation of Sheet lc

The sheet 1c was prepared by operating as reported in Example 1, except that instead of 5,6-diphenoxy-4,7-bis[5-(2,6-dimethylphenyenyl)-2-thienyl]benzo[c]1,2,5-thiadiazole (MPDTBOP), use was made of Oil Blu N (Sigma-Aldrich) in an amount equal to 26.5 ppm, obtaining the sheet 1c (dimensions 250×250×3 mm).

### EXAMPLE 4

### Preparation of Sheet 2a

In a 10-litre flask, 4.8 litres of methyl methacrylate (MMA) (Sigma-Aldrich), previously distilled in order to remove any polymerisation inhibitors, were heated under magnetic stirring, bringing the temperature to 80° C., in 2 hours. Subsequently, 480 mg of 2,2′-azobis(2-methylpropionitrile) (AIBN) (Sigma-Aldrich) (initiator) dissolved in 480 ml of methyl methacrylate (MMA) (Sigma-Aldrich), previously distilled, were added: the temperature of the mixture obtained decreases by about 3° C.-4° C. Subsequently, said mixture was heated bringing the temperature to 94° C., in 1 hour: the whole was left at said temperature, under stirring, for 2 minutes, and subsequently cooled in an ice bath obtaining a pre-polymerised polymethyl methacrylate (PMMA) syrup.

Subsequently, a mould was prepared assembled with two glass sheets having a thickness equal to 10 mm and larger dimensions equal to 700×1200 mm, separated by a polyvinyl chloride (PVC) seal with a diameter equal to 10 mm: the sheets were then mounted between metal jaws and clamped until obtaining a space between the two sheets equal to 6 mm.

Subsequently, 4.8 litres of pre-polymerised polymethyl methacrylate (PMMA) syrup obtained as described above, 300 mg of lauroyl peroxide (Sigma-Aldrich) dissolved in 480 ml of methyl methacrylate (MMA) (Sigma-Aldrich), previously distilled, an amount of 5,6-diphenoxy-4,7-bis[5-(2,6-dimethylphenyl)-2-thienyl]benzo[c]1,2,5-thiadiazole (MPDTBOP), obtained as described in Example 7 of international patent application WO 2016/046319 in the name of the Applicant above reported, equal to 17.5 ppm, an amount of N,N′-bis(2′,6′-di-iso-propylphenyl)(1,6,7,12-tetraphenoxy)(3,4,9,10-perylene-diimide (Lumogen® F. Red 305—Basf) equal to 10.8 ppm, and 5000 ppm of Tinuvin® P (Basf) were loaded into a 10-litre glass flask: the obtained mixture was kept under magnetic stirring and vacuum (10 mm Hg), for 45 minutes, at room temperature (25° C.), obtaining a degassed solution. The solution thus obtained was poured into the mould prepared as described above until it was full: subsequently, after closing the opening used for filling with a seal, the mould was immersed into a water bath at 55° C., for 48 hours. The mould was then placed in an oven at 95° C., for 24 hours (curing step), then removed from the oven and allowed to cool to room temperature (25° C.). Subsequently, the metal jaws and the seal were removed, and the glass sheets were separated, obtaining the sheet 2a (dimensions 500×500×6 mm).

### EXAMPLE 5

### Preparation of Sheet 2b

The sheet 2b was prepared by operating as reported in Example 4, except that a mould was prepared assembled with two glass sheets having a thickness equal to 10 mm and larger dimensions equal to 700×1200 mm, separated by a polyvinyl chloride (PVC) seal with a diameter equal to 10 mm: the sheets were then mounted between metal jaws and clamped until obtaining a space between the two sheets equal to 3 mm, and that instead of 5,6-diphenoxy-4,7-bis[5-(2,6-dimethylphenyl)-2-thienyl]benzo[c]1,2,5-thiadiazole (MPDTBOP) and N,N′-bis(2′,6′-di-isopropylphenyl)(1,6,7,12-tetraphenoxy)(3,4,9,10-perylene-diimide (Lumogen® F. Red 305—Basf) use was made of Oil Blue N (Sigma-Aldrich) in an amount equal to 26.5 ppm obtaining a sheet having dimensions 500×500×3 mm.

### EXAMPLE 6

### Preparation of Sheet 3a

The sheet 3a was prepared by operating as reported in Example 4, except that use was made of 5,6-diphenoxy-4,7-bis[5-(2,6-dimethylphenyenyl]benzo[c] 1,2,5-thiadiazole (MPDTBOP) in an amount equal to 35 ppm and N,N′-bis(2′,6′-di-iso-propylphenyl)(1,6,7,12-tetraphenoxy)(3,4,9,10-perylene-diimide (Lumogen® F Red 305—Basf) in an amount of 21.6 ppm obtaining a sheet having dimensions 500×500×6 mm.

### EXAMPLE 7

### Preparation of Sheet 3b

The sheet 3b was prepared by operating as reported in Example 5 except that Oil Blue N (Sigma-Aldrich) was used in an amount equal to 53 ppm, obtaining a sheet having dimensions 500×500×3 mm.

### EXAMPLE 8

### Preparation of the Photovoltaic Device with Achromatic Luminescent Solar Concentrator (Light Grey 1) (Comparative)

A photovoltaic device comprising an achromatic luminescent solar concentrator was prepared by operating as reported below.

The sheet 1a obtained as reported in Example 1 and the sheet 1b obtained as reported in Example 2, were superimposed so that the major surfaces were in direct contact with each other and, subsequently, 4 IXYS-SLMD142H01LE silicon photovoltaic cells, each having dimensions 247×6 mm and an active surface area of 14.7 cm² (one photovoltaic cell on each side) were glued to the four external sides using silicone (Loctite SI-5366). Said photovoltaic cells were connected in series and, subsequently, to a multimeter.

Finally, the major surface of the sheet 1c obtained as reported in Example 3, was placed in direct contact with the major lower surface of said sheet 1b.

The thus obtained device was placed outside on a stand and exposed directly to the sun, with the major upper surface of sheet la turned to the sun (i.e. closer to the photon source) and the electrical power generated by solar illumination was measured.

The power measurements were carried out by illuminating the entire surface of the photovoltaic device (corresponding to the surface of the exposed sheet 1a, i.e. 250×250 mm).

The current-voltage characteristics were obtained by applying an external voltage to each of said cells and measuring the photocurrent generated with a “Keithley 2602A” digital multimetre (3A DC, 10A Pulse), obtaining the following values: maximum measured power relative to the illuminated surface (P_{MAX}) (expressed in W), normalised power per m² (P) (expressed in W/m²) obtained from the value of the maximum power (P_{MAX}) and efficiency (E) calculated according to the following equation:

E (%)=P×0.1

wherein P is the power (P) (expressed in W/m²) and 0.1 corresponds to the maximum efficiency (100%) at 1 sun (1000 W/m²).

The results obtained were as follows:
maximum power (_{PMAX})=0.83 W;
power (P)=13.2 W/m²;
efficiency (E)=1.3%.

### EXAMPLE 9

### Preparation of the Photovoltaic Device with Achromatic Luminescent Solar Concentrator (Light Grey 2) (Disclosure)

A photovoltaic device comprising an achromatic luminescent solar concentrator was prepared by operating as reported below.

8 IXYS-SLMD142H01LE silicon photovoltaic cells having dimensions 247×6 mm each and an active surface of 14.7 cm² (one photovoltaic cell per side) were glued with silicone (Loctite SI-5366) to the four external sides of the sheet 2a obtained as reported in Example 4. Said photovoltaic cells were connected in series and, subsequently, to a multimeter.

Finally, the major surface of the sheet 2b obtained as reported in Example 5, was placed in direct contact with the major lower surface of said sheet 2a.

The thus obtained device was placed outside on a stand and exposed directly to the sun, with the major upper surface of sheet 2a turned to the sun (i.e. closer to the photon source) and the electrical power generated by solar illumination was measured.

The power measurements were carried out by illuminating the entire surface of the photovoltaic device (corresponding to the surface of the exposed sheet 1a, i.e. 500×500 mm).

The current-voltage characteristics were obtained as reported in Example 8.

The results obtained were as follows:
maximum power (_{PMAX})=3.2 W;
power (P)=12.8 W/m²;
efficiency (E)=1.3%.

### EXAMPLE 10

### Preparation of the Photovoltaic Device with Achromatic Luminescent Solar Concentrator (Dark Grey 3) (Disclosure)

A photovoltaic device comprising an achromatic luminescent solar concentrator was prepared by operating as reported below.

8 IXYS-SLMD142H01LE silicon photovoltaic cells having dimensions 247×6 mm each and an active surface of 14.7 cm² (one photovoltaic cell per side) were glued with silicone (Loctite SI-5366) to the four external sides of the sheet 3a obtained as reported in Example 6. Said photovoltaic cells were connected in series and, subsequently, to a multimeter.

Finally, the major surface of the sheet 3b obtained as reported in Example 7, was placed in direct contact with the major lower surface of said sheet 3a.

The thus obtained device was placed outside on a stand and exposed directly to the sun, with the major upper surface of sheet 3a turned to the sun (i.e. closer to the photon source) and the electrical power generated by solar illumination was measured.

The power measurements were carried out by illuminating the entire surface of the photovoltaic device (corresponding to the surface of the exposed sheet 3a, i.e. 500×500 mm).

The current-voltage characteristics were obtained as reported in Example 8.

The results obtained were as follows:
maximum power (_{PMAX})=4.2 W;
power (P)=16.6 W/m²;
efficiency (E)=1.6%.

### EXAMPLE 11

### Preparation of Sheet 4a

The sheet 4a was prepared by operating as reported in Example 1, except that a mould was prepared assembled with two glass sheets having a thickness equal to 10 mm and larger dimensions equal to 300×300 mm, separated by a polyvinyl chloride (PVC) seal with a diameter equal to 10 mm: the sheets were then mounted between metal jaws and clamped until obtaining a space between the two sheets equal to 6 mm, and that use was made of 5,6-diphenoxy-4,7-bis[5-(2,6-dimethylphenyl)-2-thienyl]benzo[c]1,2,5-thiadiazole (MPDTBOP) in amount equal to 17.5 ppm and N,N′-bis(2′,6′-di-isopropylphenyl)(1,6,7,12-tetraphenoxy)(3,4,9,10-perylene-diimide (Lumogen® F Red 305—Basf) in an amount equal to 10.8 ppm obtaining a sheet having dimensions 100×100×6 mm.

### EXAMPLE 12

### Preparation of Sheet 4b

The sheet 4b was prepared by operating as reported in Example 3, except that a sheet having dimensions 100×100×3 mm was obtained.

### EXAMPLE 13

### Preparation of Sheet 4c

The sheet 4c was prepared by operating as reported in Example 1, except that a mould was prepared assembled with two glass sheets having a thickness equal to 10 mm and larger dimensions equal to 300×300 mm separated by polyvinyl chloride (PVC) seal with a greater diameter equal to 6 mm, held together by metal jaws, and that use was not made of either 5,6-diphenyloxy-4,7-bis[5-(2,6-dimethylphenyl)-2-thienyl]benzo[c]1,2,5-thiadiazole (MPDTBOP) or N,N′-bis(2′,6′-di-isopropylphenyl)(1,6,7,12-tetraphenoxy)(3,4,9,10-perylene-diimide (Lumogen® F Red 305—Basf) obtaining a sheet having dimensions 100×100×6 mm.

A non-fluorescent transparent blue adhesive film (Bleu 40C from Solar Screen) was placed on the sheet thus obtained, operating as follows.

The face of the sheet obtained as reported above on which the film was placed was cleaned with a soapy solution and dried. The non-fluorescent transparent blue adhesive film was cut with a surface slightly larger than the surface of the sheet and placed on a shelf with the transparent protective sheet (liner) facing upwards. Subsequently, the transparent protective sheet (liner) was separated from the film by pulling it upwards: to facilitate the detachment, the surfaces of both the film and the transparent protective sheet (liner) were continuously wetted with the soapy solution. The sheet, again wetted with the soapy solution, was placed on the adhesive side of the wet film. The sheet was then positioned so that the film was on top of the sheet, the film was pressed firmly onto the sheet and the excess soapy solution was wiped off with a squeegee. When the sheet was dry, i.e. when the film was perfectly adhered to the sheet, the edges were trimmed by removing the excess film with a cutter.

### EXAMPLE 14

### Preparation of the Photovoltaic Device with Achromatic Luminescent Solar Concentrator (Light Grey 4) (Disclosure)

A photovoltaic device comprising an achromatic luminescent solar concentrator was prepared by operating as reported below.

A silicon photovoltaic cell IXYS-XOD17 having dimensions 22×6 mm and an active area of 1.2 cm² was glued by means of silicone (Loctite SI-5366) to one of the external sides of the sheet 4a obtained as reported in Example 11. Said photovoltaic cell was then connected to a multimeter.

Finally, the major surface of the sheet 4b obtained as reported in Example 12, was placed in direct contact with the major lower surface of said sheet 4a.

The thus obtained device was subjected to colour analysis by means of a SpectraRad™ Xpress spectrometer (mod. BSR112E) paired with appropriate software (BWSpec Software) from BWTEK_{inc} for colour coding.

For this purpose, the device was placed at the outlet of an integrating sphere and was illuminated with a 300 W OF (Ozone Free) Xenon lamp. The irradiance (or transmittance) spectrum measured with the spectrometer was processed by the paired software using the CIE1931 colour model: the x and y chromatic coordinates relative to the colour (indicated with 1 in FIG. 4, x in the axis of the abscissa axis and y in the ordinate axis) and the Y value relative to the brightness which was found to be equal to 37%, were obtained therefrom.

The absorption spectrum of the device was instead recorded by means of a Newport OSM400-DUV spectrometer using a 300 W OF Xenon lamp as a source: the results obtained are reported in FIG. 5, in which in the abscissa axis (x axis) the wavelength (λ) in nm is reported and in the ordinate axis (y axis) the optical density (Optical Density—O.D.) is reported.

Finally, the device thus obtained was inserted in a sample holder and the major upper surface of the sheet 4a was illuminated with a light source with a power equal to 1 sun (1000 W/m²) and the electrical power generated as a result of the lighting was measured.

The power measurements were carried out by illuminating the entire surface of the photovoltaic device (corresponding to the surface of the exposed sheet 4a, i.e. 100×100 mm).

The current-voltage characteristics were obtained by operating as described in Example 8 and the results are as follows:

maximum power (P_{MAX})=0.00237 W.

### EXAMPLE 15

### Preparation of the Photovoltaic Device with Achromatic Luminescent Solar Concentrator (Light Grey 5) (Disclosure)

A photovoltaic device comprising an achromatic luminescent solar concentrator was prepared by operating as reported below.

A silicon photovoltaic cell IXYS-XOD17 having dimensions 22×6 mm and an active area of 1.2 cm² was glued by means of silicone (Loctite SI-5366) to one of the external sides of the sheet 4a obtained as reported in Example 11. Said photovoltaic cell was then connected to a multimeter.

Finally, the major surface of the sheet 4c obtained as reported in Example 13, was placed in direct contact with the major lower surface of said sheet 4a.

The thus obtained device was subjected to colour analysis by means of a SpectraRad™ Xpress spectrometer (mod. BSR112E) paired with appropriate software (BWSpec Software) from BWTEK_{inc} for colour coding.

For this purpose, the device was placed at the outlet of an integrating sphere and was illuminated with a 300 W OF (Ozone Free) Xenon lamp. The irradiance (or transmittance) spectrum measured with the spectrometer was processed by the paired software using the CIE1931 colour model: the x and y chromatic coordinates relative to the colour (indicated with 2 in FIG. 4, x in the axis of the abscissa axis and y in the ordinate axis) and the Y value relative to the brightness which was found to be equal to 32%, were obtained therefrom.

The absorption spectrum of the device was instead recorded by means of a Newport OSM400-DUV spectrometer using a 300 W OF Xenon lamp as a source: the results obtained are reported in FIG. 5, in which in the abscissa axis (x axis) the wavelength (λ) in nm is reported and in the ordinate axis (y axis) the optical density (Optical Density—O.D.) is reported.

Finally, the device thus obtained was inserted in a sample holder and the major upper surface of the sheet 4a was illuminated with a light source with a power equal to 1 sun (1000 W/m²) and the electrical power generated as a result of the lighting was measured.

The power measurements were carried out by illuminating the entire surface of the photovoltaic device (corresponding to the surface of the exposed sheet 4a, i.e. 100×100 mm).

The current-voltage characteristics were obtained by operating as described in Example 8 and the results are as follows:

maximum power (P_{MAX})=0.00244 W.

1. An achromatic luminescent solar concentrator (LSC) comprising:
a first sheet comprising a matrix of transparent material and at least one first photoluminescent organic compound having an absorption range from 400 nm to 550 nm, and an emission range from 500 nm to 650 nm, and at least one second photoluminescent organic compound having an absorption range from 420 nm to 650 nm, and an emission range from 580 nm to 750 nm; and
a second sheet comprising a matrix of transparent material and at least one third organic compound, optionally photoluminescent, having an absorption range from 550 nm to 750 nm, and an emission range from 700 nm to 900 nm.

2. An achromatic luminescent solar concentrator (LSC) comprising:
a first sheet comprising a matrix of transparent material and at least one first photoluminescent organic compound having an absorption range from 400 nm to 550 nm, and an emission range from 500 nm to 650 nm, and at least one second photoluminescent organic compound having an absorption range from 420 nm to 650 nm, and an emission range from 580 nm to 750 nm; and
a second sheet comprising a matrix of transparent material and at least one non-fluorescent transparent adhesive film, said non-fluorescent transparent adhesive film being placed on the major upper surface of said second sheet.

3. The achromatic luminescent solar concentrator (LSC) according to claim 1, wherein said first and second sheets have an upper surface, a lower surface and one or more external sides.

4. The achromatic luminescent solar concentrator (LSC) according to any claim 1, wherein said first and second sheets are superimposed on each other so that the major surfaces of said first and second sheets are in direct contact with each other.

5. The achromatic luminescent solar concentrator (LSC) according to claim 1, wherein the major lower surface of said first sheet is in direct contact with the major upper surface of said second sheet.

6. The achromatic luminescent solar concentrator (LSC) according to claim 1, wherein the major upper surface of said first sheet is closer to the photon source and the major lower surface of said second sheet is more away from the photon source.

7. The achromatic luminescent solar concentrator (LSC) according to claim 1, wherein said transparent material is selected from the group consisting of: transparent polymers such as polymethyl methacrylate (PMMA), polycarbonate (PC), polyisobutyl methacrylate, polyethyl methacrylate, polyallyl diglycol carbonate, polymethacrylamide, polycarbonate ether, polyethylene terephthalate, polyvinylbutyral, ethylene-vinyl acetate copolymers, ethylene-tetrafluoroethylene copolymers, polyimide, polyurethane, styrene-acrylonitrile copolymers, styrene-butadiene copolymers, polystyrene, methyl methacrylate styrene copolymers, polyether sulfone, polysulfone, cellulose triacetate, transparent and impact resistant cross-linked acrylic compositions consisting of a brittle matrix (I) having a glass transition temperature (T_{g}) higher than 0° C. and elastomeric domains having dimensions lower than 100 nm consisting of macromolecular sequences (II) having a flexible nature with a glass transition temperature (T_{g}) lower than 0° C. (hereinafter referred to, for greater simplicity as PMMA-IR), or mixtures thereof; transparent glasses such as silica, quartz, alumina, titania, or mixtures thereof.

8. The achromatic luminescent solar concentrator (LSC) according to claim 1, wherein said at least one first photoluminescent organic compound is selected from the group consisting of:
benzothiadiazole compounds such as 4,7-di(thien-2-yl)-2,1,3-benzothiadiazole (DTB), or mixtures thereof;
disubstituted benzoheterodiazole compounds such as 4,7-bis[5-(2,6-dimethylphenyl)-2-thienyl]benzo[c]1,2,5-thiadiazole (MPDTB), 4,7-bis[5-(2,6-di-iso-propylphenyl)-2-thienyl]benzo[c]1,2,5-thiadiazole (IPPDTB), 4,7-bis[4,5-(2,6-dimethylphenyl)-2-thienyl]benzo[c]1,2,5-thiadiazole (2MPDTB), or mixtures thereof;
disubstituted diaryloxybenzoheterodiazole compounds such as 5,6-diphenoxy-4,7-bis(2-thienyl)-2,1,3-benzothiadiazole (DTBOP), 5,6-diphenoxy-4,7-bis[5-(2,6-dimethylphenyl)-2-thienyl]benzo[c]1,2,5-thiadiazole (MPDTBOP), 5,6-diphenoxy-4,7-bis[5-(2,5-dimethylphenyl)-2-thienyl]benzo[c]1,2,5-thiadiazole (PPDTBOP), 5,6-diphenoxy-4,7-bis[5-(2,5-dimethylphenyl)-2-thienyl]benzo[c]-1,2,5-thiadiazole (PPDTBOP), 5,6-diphenoxy-4,7-bis[5-(2,6-diisopropyl-phenyl)-2-thienyl]benzo[c]1,2,5-thiadiazole (IPPDTBOP), or mixtures thereof;
perylene and perylene imide compounds such as compounds known under the trade name of Lumogen® F083, Lumogen® F170, Lumogen® F240, from Basf, or mixtures thereof; and
benzopyranone compounds such as compounds known under the trade name of Coumarin 6, Coumarin 30, from Acros, or mixtures thereof;
or mixtures thereof.

9. The achromatic luminescent solar concentrator (LSC) according to claim 1, wherein said at least one second photoluminescent organic compound is selected from the group consisting of:
disubstituted benzoheterodiazole compounds such as 4,7-bis[5-(2,5-dimethoxyphenyl)-2-thienyl]benzo[c]1,2,5-thiadiazole, 4,7-bis[5-(2,6-dimethoxyphenyl)-2-thienyl]benzo[c]1,2,5-thiadiazole, 4,7-bis[5-(2,4-dimethoxyphenyl)-2-thienyl]benzo[c]1,2,5-thiadiazole, or mixtures thereof;
disubstituted diaryloxybenzoheterodiazole compounds such as 5,6-diphenoxy-4,7-bis[5-(2-naphthyl)-2-thienyl]benzo[c]1,2,5-thiadiazole, or mixtures thereof;
compounds comprising a benzoheterodiazole group and at least one benzodithiophene group such as 4,7-bis(7′,8′-dibutyl-benzo[1′,2′-b′:4′,3′-b″]ditien-5′-yl)-benzo[c][1,2,5]thiadiazole (F500), or mixtures thereof;
disubstituted naphthothiadiazole compounds such as 4,9-bis (7′,8′-dibutyl-benzo[1′, 2′-b′:4′, 3′-b″]ditien-5′-yl)-naphtho[2,3-c][1,2,5]-thiadiazole (F521), 4,9-bis(thien-2′-yl)-naphtho[2,3-c][1,2,5]-thiadiazole (DTN), or mixtures thereof;
benzothiadiazole dithiophenic compounds such as 4,7-bis(5-(thiophen-2-yl)thiophen-2-yl)benzo[c][1,2,5]thiadiazole (QTB), 4,7-di(5″-n-hexyl-2′,2″-ditien-5′-yl)-2,1,3-benzothiadiazole (QTB-ex), or mixtures thereof;
perylene compounds such as N,N′-bis(2′,6′-di-iso-propylphenyl)(1,6,7,12-tetraphenoxy)(3,4,9,10-perylene-diimide (Lumogen® F Red 305 from BASF)), or mixtures thereof; and
compounds derived from the family of fluorones such as compounds known under the trade name of Rhodamine 6G, Rhodamine 101, from Sigma-Aldrich, or mixtures thereof;
or mixtures thereof.

10. The achromatic luminescent solar concentrator (LSC) according to claim 1, wherein said at least one third organic compound, optionally photoluminescent, is selected from the group consisting of:
phenothiazine compounds substituted with alkyl and/or alkyl-amino groups such as the compound known under the trade name Toluidine blue from Sigma-Aldrich, or mixtures thereof;
phenoxazine compounds such as the compound known under the trade name Blue Nile A from Sigma-Aldrich, or mixtures thereof; and
anthraquinone compounds substituted with alkyl-amino groups such as the compound known under the trade name Oil Blue N from Sigma-Aldrich, or mixtures thereof;
or mixtures thereof.

11. The achromatic luminescent solar concentrator (LSC) according to claim 1, wherein in said first sheet, said at least one first photoluminescent organic compound is present in said matrix of transparent material in an amount ranging from 8 ppm to 200 ppm. ranging from 10 ppm to 100 ppm, even more preferably ranging from 15 to 40

12. The achromatic luminescent solar concentrator (LSC) according to claim 1, wherein in said first sheet, said at least one second photoluminescent organic compound is present in said matrix of transparent material in an amount ranging from 5 ppm to 130 ppm.

13. The achromatic luminescent solar concentrator (LSC) according to claim 1, wherein in said second sheet, said at least one third organic compound, optionally photoluminescent, is present in said matrix of transparent material in an amount ranging from 6 ppm to 150 ppm. preferably ranging from 10 ppm to 60 ppm, even more preferably ranging from 20 to 50 ppm.

14. The achromatic luminescent solar concentrator (LSC) according to claim 2, wherein said non-fluorescent transparent adhesive film is selected from the group consisting of polyethylene terephthalate (PET) films or colored polyvinyl chloride (PVC) films with high optical quality.

15. The achromatic luminescent solar concentrator (LSC) according to claim 1, wherein said first and second sheets have a thickness ranging from 1 mm to 10 mm.

16. A double glazing comprising at least one achromatic luminescent solar concentrator (LSC) in accordance with claim 1.

17. A double glazing comprising:
at least one achromatic luminescent solar concentrator (LSC) comprising a sheet comprising a matrix of transparent material and at least one first photoluminescent organic compound having an absorption range from 400 nm to 550 nm, and an emission range from 500 nm to 650 nm, and at least one second photoluminescent organic compound having an absorption range from 420 nm to 650 nm, and an emission range from 580 nm to 750 nm; and
at least one non-fluorescent transparent adhesive film glued directly on a glass of the double glazing, preferably on the innermost glass.

18. The double glazing according to claim 17, wherein said first photoluminescent organic compound is selected from the group consisting of:
benzothiadiazole compounds such as 4,7-di(thien-2-yl)-2,1,3-benzothiadiazole (DTB), or mixtures thereof;
disubstituted benzoheterodiazole compounds such as 4,7-bis[5-(2,6-dimethylphenyl)-2-thienyl]benzo[c]1,2,5-thiadiazole (MPDTB), 4,7-bis[5-(2,6-di-iso-propylphenyl)-2-thienyl]benzo[c]1,2,5-thiadiazole (IPPDTB), 4,7-bis[4,5-(2,6-dimethylphenyl)-2-thienyl]benzo[c]1,2,5-thiadiazole (2MPDTB), or mixtures thereof;
disubstituted diaryloxybenzoheterodiazole compounds such as 5,6-diphenoxy-4,7-bis(2-thienyl)-2,1,3-benzothiadiazole (DTBOP), 5,6-diphenoxy-4,7-bis[5-(2,6-dimethylphenyl)-2-thienyl]benzo[c]1,2,5-thiadiazole (MPDTBOP), 5,6-diphenoxy-4,7-bis[5-(2,5-dimethylphenyl)-2-thienyl]benzo[c]1,2,5-thiadiazole (PPDTBOP), 5,6-diphenoxy-4,7-bis[5-(2,5-dimethylphenyl)-2-thienyl]benzo[c]-1,2,5-thiadiazole (PPDTBOP), 5,6-diphenoxy-4,7-bis[5-(2,6-diisopropyl-phenyl)-2-thienyl]benzo[c]1,2,5-thiadiazole (IPPDTBOP), or mixtures thereof;
perylene and perylene imide compounds such as compounds known under the trade name of Lumogen® F083, Lumogen® F170, Lumogen® F240, from Basf, or mixtures thereof; and
benzopyranone compounds such as compounds known under the trade name of Coumarin 6, Coumarin 30, from Acros, or mixtures thereof;
or mixtures thereof,
said second photoluminescent organic compound is selected from the group consisting of:
disubstituted benzoheterodiazole compounds such as 4,7-bis[5-(2,5-dimethoxyphenyl)-2-thienyl]benzo[c]1,2,5-thiadiazole, 4,7-bis[5-(2,6-dimethoxyphenyl)-2-thienyl]benzo[c]1,2,5-thiadiazole, 4,7-bis[5-(2,4-dimethoxyphenyl)-2-thienyl]benzo[c]1,2,5-thiadiazole, or mixtures thereof;
disubstituted diaryloxybenzoheterodiazole compounds such as 5,6-diphenoxy-4,7-bis[5-(2-naphthyl)-2-thienyl]benzo[c]1,2,5-thiadiazole, or mixtures thereof;
compounds comprising a benzoheterodiazole group and at least one benzodithiophene group such as 4,7-bis(7′,8′-dibutyl-benzo[1′,2′-b′:4′,3′-b″]ditien-5′-yl)-benzo[c][1,2,5]thiadiazole (F500), or mixtures thereof;
disubstituted naphthothiadiazole compounds such as 4,9-bis (7′,8′-dibutyl-benzo[1′, 2′-b′: 4′, 3′-b″]ditien-5′-yl)-naphtho[2,3-c][1,2,5]-thiadiazole (F521), 4,9-bis(thien-2′-yl)-naphtho[2,3-c][1,2,5]-thiadiazole (DTN), or mixtures thereof;
benzothiadiazole dithiophenic compounds such as 4,7-bis(5-(thiophen-2-yl)thiophen-2-yl)benzo[c][1,2,5]thiadiazole (QTB), 4,7-di(5″-n-hexyl-2′,2″-ditien-5′-yl)-2,1,3-benzothiadiazole (QTB-ex), or mixtures thereof;
perylene compounds such as N,N′-bis(2′,6′-di-iso-propylphenyl)(1,6,7,12-tetraphenoxy)(3,4,9,10-perylene-diimide (Lumogen® F Red 305 from BASF)), or mixtures thereof; and
compounds derived from the family of fluorones such as compounds known under the trade name of Rhodamine 6G, Rhodamine 101, from Sigma-Aldrich, or mixtures thereof;
or mixtures thereof, and said non-fluorescent transparent adhesive film is selected from the group consisting of polyethylene terephthalate (PET) films or colored polyvinyl chloride (PVC) films with high optical quality.

19. A photovoltaic device (or solar device) comprising at least one photovoltaic cell (or solar cell), and at least one achromatic luminescent solar concentrator (LSC) according to claim 1.
